(19) United States
(12) Patent Application Publication
(10) Pub. No.: US 2006/0083048 A1
(43) Pub. Date: Apr. 20, 2006

(54) Multi-stable vortex states in ferroelectric nanostructure

(76) Inventors: Ivan I. Naumov, Fayetteville, AR (US); Laurent Bellaiche, Fayetteville, AR (US); Huaxiang Fu, Fayetteville, AR (US)

Correspondence Address: WRIGHT, LINDSEY & JENNINGS LLP, 200 WEST CAPITOL AVENUE, SUITE 2300, LITTLE ROCK, AR, 72201-3699, US

(21) Appl. No.: 11/151,088

(22) Filed: Jun. 13, 2005

Related U.S. Application Data
(60) Provisional application No. 60/580,940, filed on Jun. 18, 2004.
(60) Provisional application No. 60/632,040, filed on Dec. 1, 2004.

(51) Int. Cl. G11C 11/22

(52) U.S. Cl. 365/145; 365/65

(57) ABSTRACT

A ferroelectric nanostructure formed as a low dimensional nanoscale ferroelectric material having at least one vortex ring of polarization generating an ordered toroid moment switchable between multi-stable states. Such a nanostructure is capable of achieving ultrahigh recording density in non-volatile ferroelectric random access memory (NFERAM) and may have applications in piezoelectric sensors, efficient actuators, nano-scale dielectric capacitors for energy storage, and nano-scale ultrasounds for medical use.

### CROSS-REFERENCE TO RELATED APPLICATIONS

This application claims the benefit of U.S. Provisional Application No. 60/580,940 filed Jun. 18, 2004 and U.S. Provisional Application No. 60/632,040 filed Dec. 1, 2004, the disclosure of both of which are incorporated herein by reference.

### STATEMENT REGARDING FEDERALLY SPONSORED RESEARCH OR DEVELOPMENT

This work was supported by the Office of Naval Research (N00014-01-1-0365, N00014-03-1-0598, N00014-01-1-0600) and National Science Foundation (DMR-0116315, DMR-9983678). The government has certain rights in the invention.

### BACKGROUND OF THE INVENTION

The present invention relates to a method for achieving ultrahigh recording density by use of multi-stable vortex states discovered in ferroelectric nanostructures.

Bulk ferroelectrics undergo structural phase transformations at low temperatures, giving multi-stable (that is, multiple-minimum) degenerate states with spontaneous polarization. Accessing these states by applying, and varying the direction of, an external electric field is a key principle for the operation of devices such as non-volatile ferroelectric random access memories (NFERAMSs) [10]. Compared with bulk ferroelectrics, low-dimensional finite ferroelectric structures promise to increase the storage density of NFERAMs 10,000-fold [8]. But this anticipated benefit hinges on whether phase transitions and multi-stable states still exist in low-dimensional structures. Previous studies have suggested that phase transitions are impossible in one-dimensional systems [27, 28, 41], and become increasingly less likely as dimensionality further decreases [27, 28, 41, 42], thereby limiting the potential towards the capability improvement of NRERAM.

Experimental effort has been made recently in synthesizing and understanding ferroelectric (FE) nanostructures—e.g., BaTiO₃ dots [1], rods [2], wires [3], and nanotubes [4], and Pb(Zr, Ti)O₃ thin films [5,6] and nanoparticles [7]. However, it is entirely unknown whether it is possible to increase FE nonvolatile-memory density thousands fold by use of individual nanoparticles [3,8,9]. Furthermore, it is not clear whether these FE nanostructures can continue to be useful and efficient in light of miniaturizing piezoelectric transducers and actuators, ultrasonic devices, and medical imaging detectors [10,11]. These technological uses of enormous importance depend critically on whether ferroelectricity exists in these nanostructures. From a fundamental point of view, ferroelectricity is caused by atomic off-center displacements, resulting from a delicate balance between long-range (LR) Coulomb interaction and short-range (SR) covalent interaction [12]. In nanostructures, both interactions and thus their balance—are altered with respect to the bulk, since the LR interaction is truncated due to lack of periodicity, while the SR one is significantly modified near the surface boundary. Consequently, it is commonly believed [13-16] that ferroelectricity in nanostructures would disappear entirely (i.e., there is no ferroelectric off-center instability) below a critical size. This belief has recently received support from a theoretical study on BaTiO₃ thin films [17]. For FE nanoparticIes, while measurements of lattice structures (rather than polarization) are available only at large sizes (˜500 Å, Refs. [14,15]), the critical size of ferroelectricity (if any) is unknown [1-3,7]. In fact, it is not even clear whether there are any ferroelectric displacements in FE dots and/or whether these displacements are aligned to form long-range ferroelectric phases. Similarly, virtually nothing is known about the electrical and mechanical responses of FE nanoparticles to electric fields.

### BRIEF SUMMARY OF THE INVENTION

The present invention increases the data storage capability of non-volatile ferroelectric random access memory (NFERAM) using our newly discovered multiple degenerate states formed by ordered toroid moments in low dimensional nano-scale ferroelectric structures. For instance, at low temperature, ferroelectric nanodisks of lead zirconium titanate (PZT) exhibit two robust bi-stable states with clockwise or counterclockwise concentric vortex rings, and these states with opposite toroid moments can be used as the logic states to store “0” and “1” in memory devices. This approach is drastically different from—and superior to—the conventional approach where macroscopic polarization is used. In fact, macroscopic polarization does not exist in the nanodisks and thus cannot be utilized for the purpose of memory devices.

The minimum size, i.e., the diameter, of the nanodisks that display bi-stable toroid moments is demonstrated to be 2.8 nm. Using the vortex states as discovered in this invention, the ultimate storage density of this approach reaches 80 Terabits/inch².

The storage density achieved in the present invention far exceeds the current storage capability of 1 GBits/inch² using magnetic recording. This value is five orders of magnitude higher than that using the conventional approach by use of macroscopic polarization.

Storing data using toroid moments offers superiority over using the usual polarization in many respects.

The multi-stable states of different toroid moments in our approach can be conveniently switched by time-dependent magnetic fields. The latter does not require electrode contact which is challenging to make in nanoscale devices. We also found that the toroid moments can be switched by application of electric fields.

In order to overcome the so-called “cross talk” problem, each memory cell capacitor in the conventional approach is isolated from its neighbors by means of a passgate transistor. On the other hand, by using the toroid moment in our approach, this problem is eliminated since a nanodisk with rotational polarization has a closed electric flux and does not produce any strong long range electric fields that will interact with neighbors. Thus, nanostructures with toroid moments of polarization do not “communicate” with each other despite being small in size and packed more densely.

In addition to its use in NFERAMs, the discovery of ferroelectricity in nanoparticles may be used for piezoelectric sensors, efficient actuators, nano-scale dielectric capacitors for energy storage, and nano-scale ultrasounds for medical use.

### BRIEF DESCRIPTION OF THE DRAWiNGS

FIG. 1A is a graph of local-mode displacements, {uᵢ}, of the cells centered on the y=6th B plane of the 12×12×12 dot under zero electric field. The arrows give the direction of these displacements, projected on the xz plane, and the arrow length indicates the projected magnitude.

FIG. 1B is a graph of the same conditions as FIG. 1A, but under a field of E=5×10⁸ V/m applied along the z axis.

FIG. 1C is a graph of the same conditions as FIG. 1A, but under a field of E=10⁹ V/m applied along the z axis.

FIG. 1D is a graph of local-mode displacements {uᵢ} of the cells centered on the y=12th B plane of the 24×24×24 dot.

FIG. 1E is an illustration of four specific configurations of two dipoles with fixed centers but different orientations. Note that the dipole-dipole electrostatic energy increases from (i) to (iv). The dipoles axis (dotted line) is defined as the straight line connecting the centers of two dipoles.

FIG. 2A is a graph of response of the net mode-average <u_{z}> per unit cell, in unit of bulk lattice constant, as a function of electric field in quantum wires of different lengths. Four curves, from bottom to top, correspond to L_{z}=2.4, 4.8, 9.6, and 14.4 nm, respectively. The x-axis and y-axis lengths are both fixed at 4.8 nm.

FIG. 2B is a graph of the dependences of the poling field (E_{pf}) and the dielectric susceptibility (of stage I) on the wire length L_{z}. This susceptibility is different from the calculated bulk value of ˜124, since the latter does not correspond to dipole flipping.

FIG. 2C is a graph of response of the strain η₃ to the applied electric fields in four different wires considered in FIG. 2A.

FIG. 2D is a graph of the piezoelectric coefficient d₃₃ (of stage II) as a function of the wire length.

Symbols in FIGS. 2A-D show the direct results of the simulations, while lines are guides for eyes (except in FIG. 2B, where the analytically fitted result for the poling field is shown).

FIGS. 3A-C show the toroid moment G and local dipole pattern in PZT disks and rods.

FIG. 3A is a graph of toroid moments G_{x,y,z} (filled symbols, using the left axis) and average amplitude of off-center displacement <lul> (in units of bulk lattice constant a, open triangles, using the right axis) as a function of temperature for the (19,14) disk. Temperature is scaled so that the theoretical Curie temperature for bulk Pb(Zr_{0.5}Ti_{0.5})O₃ matches the experimental value (640 K). Notably, the off-center displacements <lul> exist far above the transition temperature T_{c}=550 K, and increases (rather than decrease) with temperature above T_{c}. Our simulated <lul> at 750 K is found to be ˜0.08a, which is 75% of the corresponding value at 32 K, in good agreement with the experimental NMR results in bulk PbTiO₃ (Ref. [40]) where the local distortion at T_{c}+190 K (being 0.077a for Ti) is 70% of the value at 12K. For G₂ near the critical temperature, statistical uncertainty (obtained from averaging over different number of Monte Carlo steps in simulation) is indicated by error bars. A sizable G_{y} at 500 K is due to statistical fluctuation.

FIG. 3B is a graph of contributions to the total G_{z} from each (001) plane in the (19,14) disk at 768 K and 64 K. Inset: local dipoles on the central z=7 plane, at 64 K (the magnitude of each dipole is enlarged for clarity).

FIG. 3C is a graph of local dipoles on the central x (the left panel) and y cross-section of the (7,28) rod at 64 K. Local vortices are schematically shown as circles.

FIG. 4 comprises graphs showing size dependence of properties of the A and B phases.

FIG. 4A shows the toroid moment G_{z} of phase A (triangles, using the left axis) and G_{xy} of phase B (squares, using the right axis), at 64 K.

FIG. 4B shows the critical temperatures for the A and B phases. Notably, the T_{c} of the A phase (being larger than 350 K) indicates that the toroid moments in PZT nanoparticles are conveniently ready for making a new generation of NFERAMs able to operate at room temperature.

FIG. 4C shows the dipole energy E_{dip}, total energy Eₜₒₜ per 5-atom cell, and ratio R=IE_{n-dip}/E_{dip}I, at 64 K. Open symbols: A phase (using the left axis); filled symbols: B phase (using the right axis). The size on the horizontal-axis in each figure is the diameter D for phase A (while H is fixed at 14), or height H for phase B (while D is fixed at 7). The error bars indicate the statistical uncertainty in the simulations. For those results with less than ±3% uncertainty, error bars are not shown for clarity.

### DETAILED DESCRIPTION OF THE INVENTION

We investigate, from first principles, the ferroelectric properties of BaTiO₃ colloidal nanoparticles—and, in particular, answer whether there is ferroelectricity in FE nanoparticles and how these particles respond to applied electric fields. These properties are found to be unusual and differ from what is commonly believed.

Here, we further develop and use a first-principles-derived effective-hamiltonian approach [18,19] coupled with Monte Carlo simulations. (Ideally, one would like to use direct first-principles density-functional theory, but this is currently computationally impracticable.) The effective hamiltonians of Refs. [18,19], which are derived from first principles and possess a comparable accuracy, have been successfully applied to many FE materials, including simple BaTiO₃ [20], PbTiO₃ [21], and KNbO₃ [22] systems, and complex Pb(Zr, Ti)O₃ [19] and Pb(Sc, Nb)O₃ [23] solid solutions. In this approach, local modes {uᵢ} (i is the cell index) describe the ferroelectric instability in individual 5-atom cells; ui are associated with local electrical dipoles Pᵢ via Pᵢ=Z*uᵢ(where Z* is the effective charge of the local mode).

Compared to the original method detailed in Ref. [18], two new developments are made here in order to be able to study FE nanoparticles: (i) No supercell periodic boundary conditions are imposed, and the LR dipole-dipole interaction is performed in real-space (inside the nanoparticles) rather than in reciprocal space. Our simulations with open-boundary condition precisely mimic the experimental situations [3,5,6] in which polarizations in FE wires and films are probed by noncontact electrostatic forces without metallic electrodes. By contrast, the calculations of BaTiO₃ thin films in Ref. [17] assume a short-circuit boundary condition with metallic electrodes surrounding the films. Also note that, in our real-space implementation without artificial periodicity for finite systems, the potential field generated by every dipole in the nanoparticles—including the depolarization field produced by the charges (i.e., uncompensated dipoles) at nanoparticle surfaces—is precisely computed and properly accounted for. (ii) Existence of the vacuum surrounding nanoparticles will cause surface-induced atomic relaxations and cell-shape changes (thus affecting both local modes and local inhomogeneous strains) near the nanoparticle surfaces. To account for the effect of atomic relaxations on local modes, an interaction between local modes at surfaces and the vacuum (denoted as mode-vacuum interaction) is added in the hamiltonian. Similarly, an interaction between the inhomogeneous strains and the vacuum (denoted as local strain-vacuum interaction) is added to account for the effect of cell-shape changes on local strains. The parameters of these two SR interactions—whose contributions to total energy are analytically similar to the species-dependent intersite coupling terms of Ref. [19]—are determined from first-principles local-density-approximation (LDA) calculations on BaTiO₃ surfaces. Our effective hamiltonian for FE dots thus includes the dominating effects caused by the vacuum on charge redistribution, atomic relaxations, and cell-shape changes near the surfaces. We assume that the surfaces of nanoparticles are BaO terminated, since they have lower energies than TiO-terminated surfaces [24]. Other interaction parameters used here (to describe the FE material per se) are those of Ref. [20] for bulk BaTiO₃, since Ref. [17] demonstrates that these parameters do not change significantly when going from bulk to nanostructures. Local modes {uᵢ} at low temperatures are obtained via temperature-annealing Monte Carlo simulations. A pressure of −4.8 GPa is used in simulations to correct the LDA error in lattice constant. Results presented here are obtained for 50 K.

For simplicity, we assume BaTiO₃ dots to be rectangular, since adopting a spherical or a square cross section leads only to a minor difference. The rectangular dots are denoted as nₓ×n_{y}×n_{z}, where nₓ, n_{y}, n_{z} are the numbers of five-atom cells contained in the dots along the pseudocubic [100], [010], and [001] directions, respectively. The average size of a nanoparticle is thus given by L=(LₓL_{y}L_{z})^{1/3}, where L=nᵢa(i=x, y, z) are the lengths along the three Cartesian axes (a=4.0 Å is the lattice constant of BaTiO₃). For the clarity of demonstration, our prediction for local modes {uᵢ} will be presented on a certain perovskite B-site plane, which is specified by its normal direction and its order index among the equivalent planes (e.g., the y=6 plane is the 6th plane having a normal direction along the y axis).

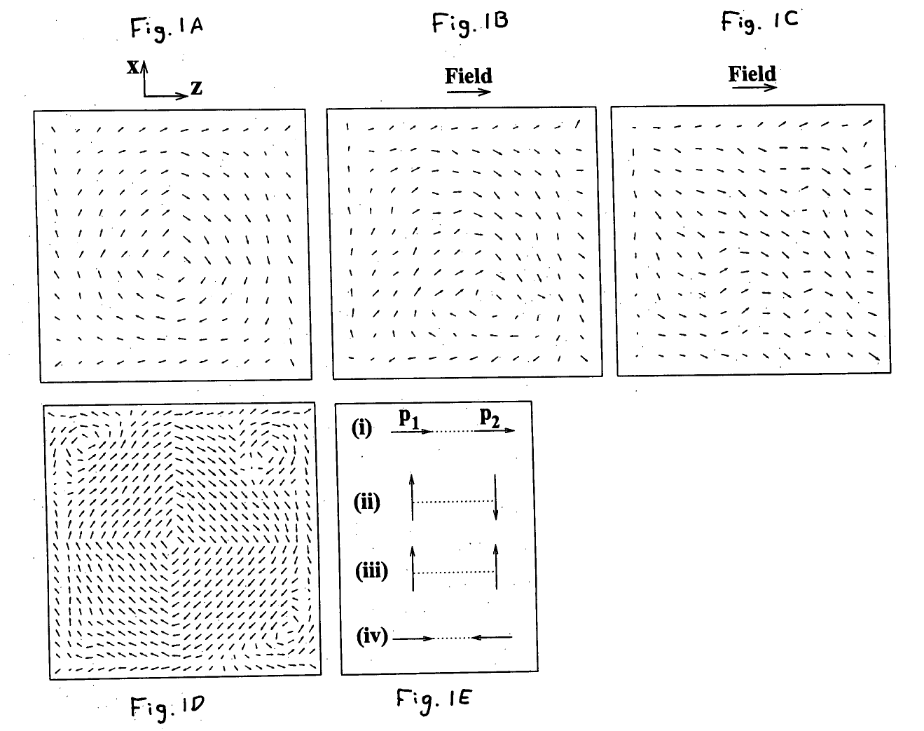

Local modes {uᵢ} on the y=6 plane of a 12×12×12 dot are depicted in FIG. 1A. Significant ferroelectric off-center displacements can be clearly seen in this small (L=4.8 nm) dot. The local-mode magnitude <lul>, averaged over all 5-atom cells, is 0.043a in this dot. This is remarkably large and comparable with the value of 0.039a found in bulk BaTiO₃. These large off-center displacements, indicating the existence of significant dipoles in each cell, have an important implication—that is, a large amount of macroscopic polarization can be generated by aligning these local dipoles with electric fields. Note that this effect cannot be achieved in nonferroelectric nanoparticles without off-center displacements, unless a huge electric field is applied. In fact, other calculations we performed (not shown here) predict that large off-center displacements yielding a magnitude <lul>]=0.052a occur even in the tiny 4×4×4 dot (L =1.6 nm). Conceivably, such a small size is likely the limit achievable in experiments. These results thus suggest that there is virtually no critical size for ferroelectric instability in nanoparticles.

For the dipoles on the dot surfaces, analysis of FIG. 1A shows that the parallel-to-surface components of these dipoles prefer to point along opposite directions on two opposite surfaces, while the (small) normal-to-surface components tend to bulge out due to the surface-induced atomic relaxations. FIG. 1A further reveals that the local dipoles in small dots prefer to rotate from cell to cell, forming an unusual and complex “vortex-like” pattern (similar to the ones found in some magnetic compounds). Note that this vortex pattern in FE dots is different from the ferroelectric pattern in bulk (where all dipoles are aligned along the same direction, as predicted by similar-size supercell effective-hamiltonian simulations or assumed in five-atom first-principles calculations). Interestingly, as a result of the dipole pattern in FIG. 1A the total macroscopic polarization is found to be zero (i.e., [u]=0). Furthermore, we found that the vortex pattern of displacements does not alter appreciably when turning off and on the mode-vacuum SR interaction. This suggests another important conclusion, namely, that ferroelectric instability in dots is not much affected by the surface local environments or, equivalently, that the capping organic matrix materials used in experiments should not affect the ferroelectric properties of the dots. Unlike in Ref. [17] where charges in metallic electrodes are able to move freely and will thus cause strong screening, the organic capping materials used in colloidal FE nanoparticles [1,2,7] are insulators of large gap (˜10 eV) and the resulting screening is very small. As the dot increases in size to 24×24×24, the local FE displacements tend to order between each other via the formation of eight rather uniform ferroelectric domains as shown in FIG. 1D. The polarization of each domain in FIG. 1D is found to point along one of the eight pseudocubic [±1±1±1] directions. The macroscopic polarization of the entire dot remains as zero.

The displacement pattern in FIG. 1A results from a new balance (with respect to the bulk case) between the LR and SR interactions in dots, and can be simply explained as follows. First, let us consider the LR dipole-dipole interaction alone for two isolated dipoles (with four specific orientations illustrated in FIG. 1E); the lowest-energy configuration is that these two dipoles both point at the same direction along the dipole axis (case (i) in FIG. 1E). Indeed, it can be seen in FIG. 1A that the dipoles belonging to a same row have their parallel-to-dipole-axis (i.e., the z axis) components aligned along the same direction. (Note that dipoles on the dot surfaces are exceptions, see below.) Next, let us select a given row in FIG. 1A, and note that the dipoles located near the nanoparticle surfaces in this row tend to have large parallel-to-surface (“in-plane”) components with their normal components suppressed by the vacuum; these in-plane components (being perpendicular to the dipole axis) shall flip their directions (since case (ii) has a lower energy than case (iii) in FIG. 1E). However, this flip of the component perpendicular to the z axis does not occur within the nearest cell (see FIG. 1A), since we found that it will otherwise drastically increase the short-range energy. Instead, the flip occurs across the entire dot, forming the unusual pattern in FIG. 1A.

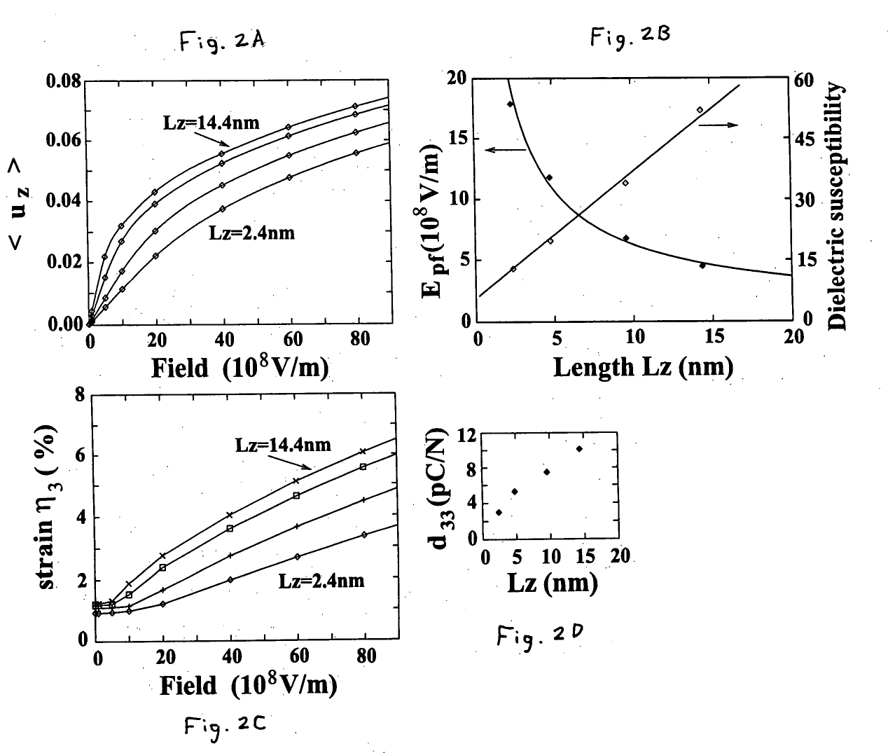

Now we turn our attention to electric-field effects in nanoparticles. More precisely, we are particularly interested in revealing the size dependences of these effects. We decide to elongate the nanoparticles only along the z axis (that is, the applied-field direction) to mimic quantum wires, partly because increasing the dot size along all three dimensions is computationally prohibitive. FIG. 2A shows the resulting net z axis mode average (u_{z}) and clearly indicates that the same electric field induces a larger polarization per five-atom cell in a long wire than in a short wire. Field effects in FE dots thus depend substantially on sizes. This is the first time that the size dependence of field-induced polarization is firmly established (to our knowledge). FIG. 2A further reveals that a small electric field in long wires drives a rapidly increasing polarization and thus easily turns a (macroscopically) paraelectric FE nanostructure into a (macroscopically) ferroelectric phase. Here we define the poling field E_{pf} as the field that is needed to drive a net average displacement (u_{z}) equal to the bulk value of 0.02a. The poling fields for different-size wires are given in FIG. 2A, and drastically decrease when increasing size. More precisely, fitting our theoretical data in FIG. 2B as a function of size gives E_{pf}=38.1966/L_{z}ⁿ with n=0.7821, where E_{pf} is in unit of 10⁸ VWm and L_{z} in unit of nm.

Our predictions provide explanations and/or suggest reinterpretations of many experimental results. For instance, no detectable polarizations were probed by electrostatic force microscopy along the perpendicular directions of both as-deposited BaTiO₃ nanowires [3] and as-grown PZT films [5]. This can be simply explained by the vanishing net polarizations we found in dots and in wires (see e.g., FIG. 1A). Our findings further suggest that the nondetectable polarization in PZT films may not be due to the electrostatic passivation of additional charges at sample surfaces as it was speculated [5], but rather results from the “intrinsic” arrangement of local dipoles. Moreover, it was found experimentally [3] that a field of 3.6×10⁸ V/m is needed to “write” a polarization along the perpendicular direction of an 18 nm diameter BaTiO₃ wire, which is in excellent agreement with our predicted value of 3.98×10⁸ V/m obtained from the formula given above.

We now provide a microscopic understanding of the field-induced responses in FE dots. We find that the responses in FIG. 2A can be separated into three stages according to their (u_{z})-vs-field behaviors, and here we use the 12×12×12 dot to illustrate these stages. (I) At stage I (that occurs at field E<10⁹ V/m), the dipoles pointing opposite to the field direction are sequentially flipped (FIG. 1B). The flip process occurs first near the domain boundary, while dipoles on the dot surface are found to be more resistant to the applied field (see FIG. 1B). Stage I generates a polarization that varies linearly with the field strength (FIG. 2A). The slope (i.e., dielectric susceptibility) is given in FIG. 2B for different wires and is found to increase linearly with the wire length. (2) At stage II (10⁹<E<4×10⁹ V/m), the dipoles start to rotate towards the field direction as the dipole flips of stage I have been completed (FIG. 1C). Stage II differs from the polarization rotation in bulk [25,26]in that, prior to the rotation, local dipoles in dots are not parallely aligned as in bulk. Interestingly, this second stage yields a strong nonlinear field dependence of polarization (FIG. 2A). (3) At stage III (E>4×10⁹ V/m), with the dipoles having all been previously rotated along the field direction, the magnitude of each dipole then starts to be enlarged by the field, resulting in a nearly linear field-dependent polarization again.

Finally, we examine the electromechanical response in FE wires. The field-induced η₃ strains are depicted in FIG. 2C. At stage I, the strain response is found to be surprisingly small though there is a rapid increase in polarization, which suggests that polarization does not couple with strain during the dipole flipping process. At stage II, the strain increases evidently with the field strength (FIG. 2C); the strain-vs-field slope is the piezoelectric coefficient d₃₃. The d₃₃ values are given in FIG. 2D for different wires, and exhibit a monotonous increase with size. Interestingly, the d₃₃ coefficients in nanoparticles (˜10 pC/N) are found to be much smaller than in bulk (˜77 pC/N), suggesting that the electromechanical response can be drastically modified by varying sizes.

In summary, we find: (i) Large ferroelectric off-center displacements exist in very small (˜5 nm) dots. This result solves a long-standing puzzling question in experiments, namely, whether there exists ferroelectricity in colloidal FE dots under zero field. This discovery also opens a possibility of tremendous increase in FE-memory density. (ii) FE displacements in dots exhibit an unusual and hitherto-unknown vortex pattern. This pattern is found to cause rather peculiar field-induced polarization responses. (iii) The ferroelectric instability in dots is found to be robust against the organic capping materials. (iv) The poling field is predicted to decrease drastically with increasing size, which is important for practical controls of FE nanostructures by use of external electric fields. (v) The polarization responses of FE dots at stage II are found to be strongly nonlinear, while the electromechanical responses in dots are found to be remarkably smaller than those in the bulk.

We perform further ab initio studies of ferroelectric nanoscale disks and rods of technologically-important Pb(Zr,Ti)O₃ solid solutions, and demonstrate the existence of previously unknown phase transitions in zero-dimensional ferroelectric nanoparticles. The minimum diameter of the disks that display low-temperature structural bistabilitv is determined to be 3.2 nm, enabling an ultimate NFERAM density of 60×10¹² bits per square inch—that is, five orders of magnitude larger than those currently available [30]. Our results suggest an innovative use of ferroelectric nanostructures for data storage, and are of fundamental value for the theory of phase transition in systems of low-dimensionalitv.

One main difference between ferroelectric (FE) nanostructures and (infinite) bulk materials is the existence in the former of depolarizing fields, because of the uncompensated charges at the surface [43]. The depolarizing field (the magnitude of which can-be as high as 10⁴ kV cm⁻¹) is able to quench spontaneous polarization; this is consistent with the recent experimental and theoretical findings that the ground states of finite free-standing FE samples remain paraelectric at very low temperature (50K) [3,32]. To induce sizable polarizations, external electric fields [3,5]—or equivalently, as pointed out in Ref. [32], short-circuit boundary conditions [17,21]—are needed to screen the depolarizing field. As the external fields vanish, the induced polarizations are expected to relax to the ground state of non-polarity, with the relaxation time decreasing exponentially with reducing size, which hampers the miniaturization of nanoscale NFERAMs. Further, a large external electric field is needed to reverse the polarization and to swap charges in electrodes in order to rewrite data bits.

Whether phase transitions still occur in low-dimensional structures has been a subject of long-standing fundamental interest for understanding and revealing collective interactions [27,28,41,42]. For instance, Ref. [27] predicts that the thermal fluctuation of acoustic phonons and the entropy due to domain formation disfavor long-range ordering of local dipoles in one-dimensional systems, without any transition to phases with spontaneous polarization. Similarly, using a spin-lattice model, Mermin and Wagner showed that no spontaneous magnetic ordering exists in one-dimensional systems [28].

Here we report state-of-the-art ab initio simulations, which lead to the discovery that (1) phase transitions do in fact exist in zero-dimensional FE nanostructures; (2) these phase transitions differ profoundly from those occurring in bulk material, in the sense that they lead to the formation of spontaneous toroid moment [44] rather than spontaneous polarization, below a critical temperature; (3) the unusual characteristics of the resulting low-temperature phases promise the generation of new NFERAM devices with remarkable capabilities. Our simulations also reveal the precise role of finite-size effects on toroid moments.

We study free-standing nanoparticles of perovskite Pb(Zr_{0.5}Ti_{0.5})O₃ (PZT) solid solution—the most promising candidate for nano-NFERAM and nano-MEMS [8, 33]. The investigated nanoparticles all have a cylindrical shape, with diameter D and height H (both in units of bulk lattice constant a=4 Å); the cylindrical z-axis is chosen to be along the pseudocubic [001] direction, with the x and y axes along the [100] and [010] directions, respectively. Particles with D>H and D<H are referred to as disks and rods, respectively, and each particle is named as (D,H). A variety of combinations of D and H, ranging from 5 to 30, are considered here.

Technically, a first-principles-derived effective hamiltonian [18,19] is used to determine the energetics and local dipoles in each perovskite five-atom cell. (This hamiltonian has been shown to reproduce well the observed thermodynamic behavior of bulk PZT, including the occurrence of an unusual monoclinic phase for a small range of Ti composition [19,35].) Nanoparticles surrounded by vacuum are mimicked without periodic boundary conditions; details of our approach for FE nanoparticles are described elsewhere [31]. The validity of this approach was demonstrated by the accurate determination of the poling fields in BaTiO₃ dots [31], as well as by the theoretical study of ultrathin PZT films under compressive strains that yields a 180° stripe domain [45], in agreement with experimental observation [46]. Here we focus on atomically disordered PZT nanostructures, which are consistent with the chemical nature of bulk PZT [36].

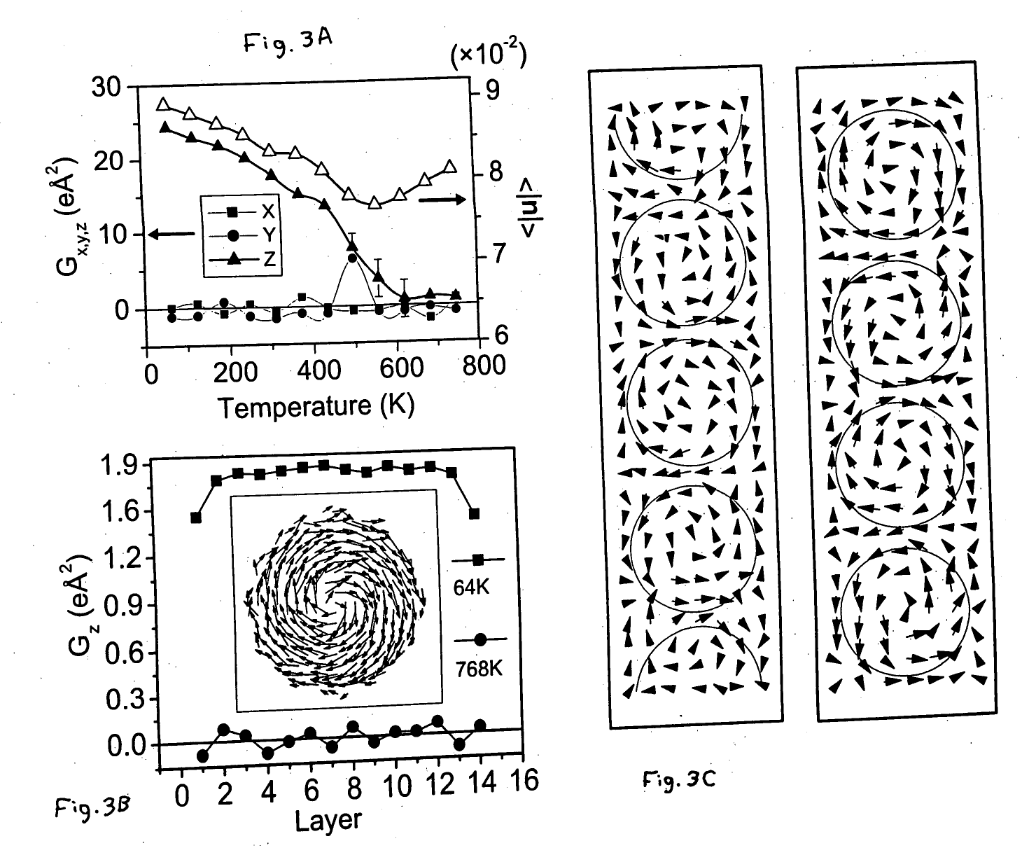

For all simulated nanoparticles, the total net polarization P=N⁻¹ Σpᵢ (where pᵢ is the local dipole of the cell i located at Rᵢ, and N is the number of cells in the simulation) is found to be null down to 10 K. Unlike previous studies that mainly focus on spontaneous polarization as the evidence of phase transition, we, on the other hand, discover a new order parameter—namely, the toroid moment G of polarization—defined as
G=(2N)⁻¹ΣᵢRᵢ×pᵢ (1)
FIG. 3A shows that the z-component of toroid moment, G_{z}, of the (19,14) disk increases sharply below 600K while being zero at higher temperature (the Gₓ and G_{y} components remain nearly null at all temperatures). This indicates that an ordering associated with local dipoles occurs in this zero-imensional disk below a certain critical temperature, T_{c}. We further found that the specific heat (not shown here) exhibits a hump around 550K, which provides a quantitative measure of T_{c} and further confirms the existence of a phase transition.

In order to gain a microscopic insight into this unusual phase transition, FIG. 3B shows the contribution of each (001) plane in the (19,14) disk to the total G_{z} at high (768K) and low (64 K) temperature. One can clearly see that the moments of individual planes are all small and random at 768 K. On the other hand, these moments markedly increase in magnitude, and also spontaneously order along the z direction, when the temperature is lowered. These low-temperature local toroid moments are predicted to be nearly identical in each (001) plane, except near the surface layers. The resulting ordered phase, which we denote as phase A, is characterized by either clockwise or anti-clockwise vortices in each z plane, with a vortex in the central z plane displayed in the inset of FIG. 3B.

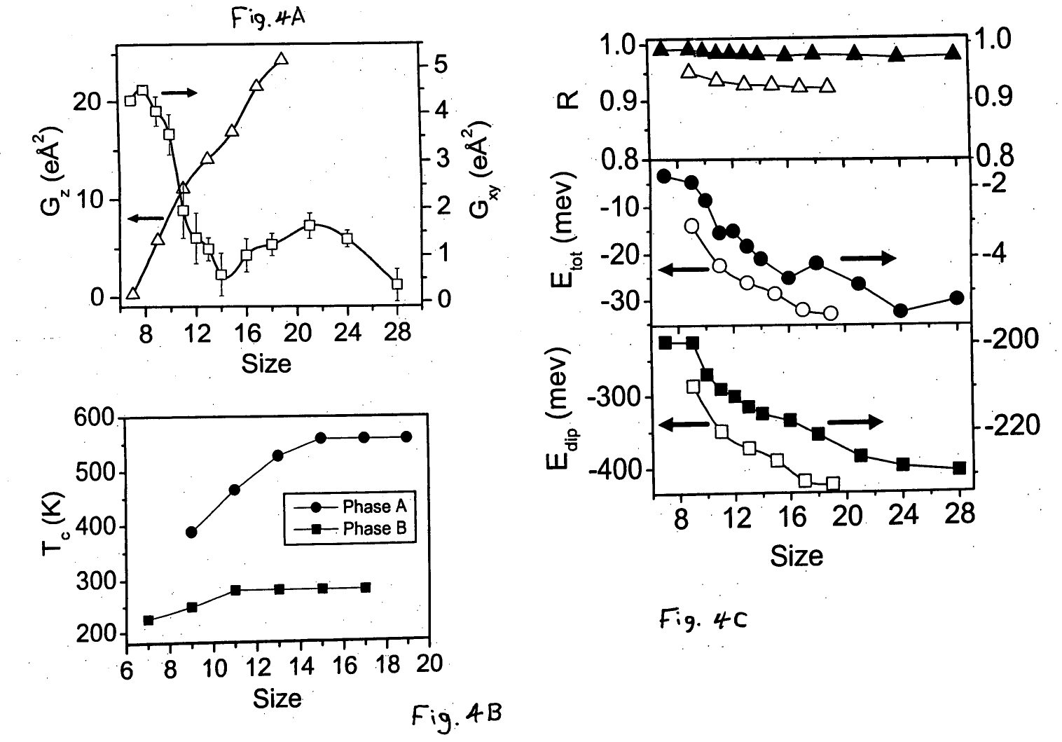

We now explore how this peculiar A phase, and its characteristics, evolve as a function of diameter D for a fixed height H (chosen here to be 14). The most notable results are that: (1) the A phase is found to be stable (at low temperature) “only” above a critical value of D—denoted by D_{c,A}, and equal to 8 when H=14; (2) low-temperature toroid moment G_{z} increases in magnitude as the diameter becomes larger, with an inflexion point occurring in the G₂-D curve when meeting the D=H equality—that is, when nanorods become nanodisks (see FIG. 4A); (3) the T_{c} of nanorods (D<H) markedly increases as D increases, whereas nanodisks (D>H) exhibit a diameter-insensitive T_{c} (see FIG. 4B).

Result (1), indicated above, raises the question of what structurally happens at low temperature in FE nanoparticles with diameter smaller than D_{cA}. We numerically found that below a second critical diameter (to be referred to as D_{cB} and equal to 6 when H=14), no vortices exist in any plane, yielding a vanishing total toroid moment. On the other hand, substantial off-center displacements still occur, with the spontaneous polarization being still null. The resulting macroscopically “non-polar” and “non-toroidal” phase can be characterized as spin-glass type [38] and will be denoted as the SG phase. Another feature that we discover is that the A phase does not directly transform into this glass-type SG phase, when decreasing the diameter. In fact, when D ranges between D_{c,A} and D_{c,B}, a new structural phase—to be referred to as the B phase—forms. The arrangement of the local dipoles in this B phase is depicted in FIG. 3C, for the (7,28) nanorod and at low temperature.

Like the A phase and unlike the SG phase, phase B exhibits vortices with non-zero local toroid moments. However, unlike the A phase, the toroid moments of phase B have x and y components but no z component. Specifically, FIG. 3C shows that, in the (7,28) nanorod, four vortices appear in the central x (as well as y) cross-section—and intriguingly, each vortex is found to have a diameter nearly the size of D, with two neighboring vortices having opposite local toroid moments. The total toroid moment, unlike the local toroid moments, is thus relatively small in the B phase. This B phase can be thought as an intermediate phase between the A phase (characterized by large local and total toroid moments) and the SG phase (for which there is neither local nor total toroid moment), occurring via the quasi-annihilation of the total, but not local, toroid moment. Furthermore, FIG. 3C shows that the edges of the vortices on the x plane go through the centers of the vortices in the y plane: two sets of vortices in the B phase are therefore interconnected like links in a chain. As a result, the local toroid moments adopt a helix-like ordering with a period λ=2D, and this B phase is 16-fold degenerate.

FIG. 4A shows the evolution of the magnitude of total tbroid moment G_{z}=(Gₓ²+G_{y}²)^{1/2} in the B phase, as a function of the rod height at low temperature. We can see that this magnitude is relatively small with respect to the G_{z} of the A phase, and decreases non-monotonically as H increases. Moreover, FIG. 4B shows that the critical temperature at which the B phase forms is considerably lower than the T_{c} at which the A phase appears.

The local dipoles in ordered A phase bear a remarkable resemblance to the molecule orientations in the so-called smectic (respectively, cholesteric) phase of liquid crystals [37]—and the ordered dipoles in B phase resemble orientations in the cholesteric phase. The above FE patterns in A or B phases are found to be robust, in the sense that they do not depend significantly on the surface termination of nanoparticles, or on whether the short-range interaction between vacuum and the local modes beyond the first surface layer is included or not in the simulations, since these patterns are predominantly determined by the long-range electrostatic interaction.

To understand the stabilities of phases A and B, the total energy Eₜₒₜ and dipole energy E_{dip} were determined, and are shown in FIG. 4C at a fixed and low (64 K) temperature. We find that the delicate balance between non-dipolar and dipolar interactions (such balance is believed to play a critical role in affecting the collective behavior of ferroelectrics [12], and is here described quantitatively by the ratio R=IE_{n-dip}/E_{dip}I, where E_{n-dip}=Eₜₒₜ−E_{dip}) is, surprisingly, mostly size-independent—being 0.92 and 0.97 for the A and B phases, respectively. However, the stability energy Eₜₒₜ progressively decreases in magnitude when D is reduced in phase A, which explains the size-dependence of the critical temperature (for the A phase to appear) in FIG. 4B. Furthermore, IEₜₒₜI of phase B (˜4 meV) is substantially smaller than its counterpart in phase A, hence leading to much lower critical temperatures.

The occurrence of phase transitions in zero-dimensional nanoparticles, in contrast with the predictions for one-dimensional systems [27,28], has a rather simple explanation. FE domains prevent phase transitions from occurring in one-dimensional systems because they are able to lower the Helmholtz free energy F=Eₜₒₜ−TS by increasing the entropy S. On the other hand, these domains become energetically unfavorable in zero-dimensional nanostructures (therefore allowing the existence of phase transitions) because the typical size dPD of three-dimensionally confined zero-dimensional domains (denoted as particle domains) is on the order of 100 nm according to experimental measurement [47] and thus substantially larger than the size of the studied nanoparticles. We shall point out that d_{PD} is much larger than the size of planar domains in bulk materials [48], because the small surface-to-bulk ratio in the latter case decreases the strain energy at domain interface and thus allows narrower domains. Also, d_{PD} is significantly different (as it should be) from the small size (˜2 nm) of stripe domains found in compressed ultrathin films [45, 46] where the substrate-enhanced out-of-plane polarization causes the attractive electrostatic interaction between different domains to become dominating, and in contrast, the strain energy at the domain interface due to short-range bond distortion plays only a minor role (which explains why the domain size can be small). Theoretical determination of d_{PD} is hindered by the limits of computing facilities. In either A or B phase, the local dipoles are ordered in a specific way that minimizes the depolarizing field, while simultaneously forming toroid moments, as in some magnetic systems [39]. A possible alternative way to eliminate the depolarizing field is to form 180° domains with polarization in each region pointing along +z or −z direction. This configuration is found, however, to be less stable by our constrained simulation (in which only the z component of each dipole is non-zero and allowed to relax): the energy per 5-atom cell in the (19,14) disk of such 180° domains is determined to be −11 meV, much higher than that of the ground state with toroid moment (−32 meV).

We now consider if the existence of a macroscopic toroid moment, as in phase A—rather than a spontaneous polarization, as in bulk ferroelectrics—can lead to the design of new or improved technological devices. Here it is important to realize that phase A is bistable (that is, the toroid moment can be equivalently parallel or anti-parallel to the z axis). Unlike the situation in bulk ferroelectncs where states with differently-oriented polarization can be accessed via a static external electric-field, we can switch from one minimum of phase A to the other by applying a time-dependent magnetic field. This magnetic field, generating a curling electric field via ∇×E=−∂B/∂t, interacts with the total toroid moment of the PZT particles, as described by the energetic term Eᵢₙₜ=−(2N)⁻¹ Σᵢpᵢ[Rᵢ×(∇×E)]G ∂B/∂t. The coercive field ∂B/∂t to switch the toroid moment of the (19,14) disk is estimated from the total energy Eₜₒₜ to be 1.6 mV/Å² (the real coercive field may be different because of nucleation and tunneling).

Storing data using switchable macroscopic toroid moment could be superior to using spontaneous polarization, because generating a magnetic field—unlike the generation of electric field—does not require electrode contact which is challenging to make in nanoscale devices. Furthermore, a large number of particles have to be arranged into regular arrays for memory nanodevices to be efficient, but they should not interact strongly (in order to avoid the so-called “cross-talk” problem). Phase A does not exhibit any macroscopic polarization, nor produce a strong electric field that has a long-range character. The vortex structure of phase A in a single nanoparticle can therefore be switched without modifying the states of its neighboring particles. Consequently, the toroid carriers of information can thus be packed considerably more densely than the conventional carriers of polarization, giving rise to a marked improvement in the density of ferroelectric recording. For instance, the minimum diameter that we found being able to generate hi-stable toroid states is 3.2 nm. This produces an ultrahigh storage density of 60 Tbit inch⁻², which is five orders of magnitude larger than current NFERAM capability [30] of 0.2 Gbit inch⁻². Such a promising capability also far surpasses the 1 Gbit inch⁻² density of typical magnetic recording.

We also examined the electric field generated by the toroid phase in the (19,14) disk, and found that this field is measurable in the proximity of the nanodisk (being about 5×10⁶ Vm⁻¹ at 2 nm above the disk), though it decays away quickly (thus implying that virtually no cross-talking occurs). Furthermore, the electric-field pattern (namely, the spatial dependence of the field magnitude and direction) generated by the toroidally-ordered dipoles is found to be very different from that generated by aligned local polarizations. Measuring the electrostatic field using atomic-force-microscope tips may thus confirm the existence of toroid moments and read the memory bits. The toroidally ordered structure might also be revealed by studying the fine structure of synchrotron x-ray diffraction of nanodisk arrays [46].

We thus hope that our results will not only lead to more interest in fundamental knowledge of phase transitions in ferroelectrics, but will also initiate an innovative approach for using FE nanostructures in devices with unprecedented performance.

### REFERENCES

[1] S. O'Brien, L. Brus, and C. B. Murray, J. Am. Chem. Soc. 123, 12085 (2001).
[2] J. J. Urban, W. S. Yun, Q. Gu, and H. Park, J. Am. Chem. Soc. 124,1186 (2002).
[3] W. S. Yun, J. J. Urban, Q. Gu, and H. Park, Ferroelectric properties of individual barium titanate nanowires investigated by scanned probe microscopy, Nano. Lett. 2, 447-450 (2002).
[4] Y. Luo et al., Appl. Phys. Lett. 83, 440 (2003).
[5] C. H. Ahn et al., Local nonvolatile electronic writing of epitaxial Pb(Zr_{0.52}Ti_{0.48})O₃/SrRuO₃ heterostructures, Science 276, 1100-1103 (1997).
[6] T. Tybell, C. H. Ahn, and J. -M. Triscone, AppI. Phys. Lett. 75, 856 (1999).
[7] C. Liu et al., J. Am. Chem. Soc. 123, 4344 (2001).
[8] J. F. Scott and C. A. Paz de Araujo, Ferroelectric memories, Science 246, 1400-1405 (1989).
[9] O. Auciello, J. F. Scott, and R. Ramesh, Phys. Today 51, No. 7, 22 (1998).
[10] M. E. Lines and A. M. Glass, Principles and Applications of Ferroelectrics and Related Materials (Clarendon, Oxford, 1979).
[11] K. Uchino, Piezoelectric Actuators and Ultrasonic Motors (Kluwer Academic, Boston, 1996).
[12] R. E. Cohen, Origin of ferroelectricity in perovskite oxides, Nature 358,136-138 (1992).
[13] S. Li et al., Jpn. J. Appl. Phys., Pt. 1, 36, 5169 (1997).
[14] S. Chattopadhyay et al., Phys. Rev. B 52,13177 (1995).
[15] K. Ishikawa et al., Jpn. J. Appi. Phys., Pt. 1, 35, 5196 (1996).
[16] T. Maruyama et al., Appl. Phys. Lett. 73, 3524 (1998).
[17] J. Junquera and Ph. Ghosez, Critical thickness for ferroelectricity in perovskite ultrathin films, Nature 422, 506-509 (2003).
[18] W. Zhong, D. Vanderbilt, and K. M. Rabe, Phase transitions in BaTiO₃from first principles, Phys. Rev. Lett. 73,1861-1864 (1994).
[19] L. Bellaiche, A. Garcia, and D. Vanderbilt, Finite-temperature properties of Pb(Zr₁₋ₓTiₓ)O₃ alloys from first principles, Phys. Rev. Lett. 84, 5427-5430 (2000).
[20] J. Iniguez and D. Vanderbilt, Phys. Rev. Lett. 89,115503 (2002).
[21] Ph. Ghosez and K. M. Rabe, Microscopic model of ferroelectricity in stress-free PbTiO₃ ultrathin films, Appl. Phys. Left. 76, 2767-2769 (2000).
[22] H. Krakauer, R. Yu, C. Z. Wang, and C. Lasota, Ferroelectrics 206, 133 (1998).
[23] A. M. George, J. Iniguez, and L. Bellaiche, Nature (London) 413, 54 (2001).
[24] J. Padilla and D. Vanderbilt, Phys. Rev. B 56,1625 (1997).
[25] H. Fu and R. E. Cohen, Nature (London) 403, 281 (2000).
[26] A. Garcia and D. Vanderbilt, Appl. Phys. Lett. 72, 2981 (1998).
[27] L. D. Landau and E. M. Lifshitz, Statistical Physics (Butterworth-Heinemann, Oxford, 2000).
[28] N. D. Mermin and H. Wagner, Absence of ferromagnetism or antiferromagnetism in one-or two-dimensional isotropic Heisenberg models, Phys. Rev. Lett. 17, 1133-1136 (1966).
[29] W. Kanzig, Space charge layer near the surface of a ferroelectric, Phys. Rev. 98, 549-550 (1955).
[30] S. -H. Kim et al., Scaling issues of Pb(Zr,Ti)O₃ capacitor stack for high, density FeRAM devices, J. Korean Phys. Soc. 42, S1417-S1419 (2003).
[31] H. Fu and L. Bellaiche, Ferroelectricity in barium titanate quantum dots and wires, Phys. Rev. Lett. 91, 257601 (2003).
[32] B. Meyer and D. Vanderbilt, Ab initio study of BaTiO₃ and PbTiO₃ surfaces in external electric fields, Phys. Rev. B 63, 205426 (2001).
[33] F. D. Morrison et al., Ferroelectric nanotubes, Rev. Adv. Mater. Sci. 4,114-122 (2003).
[34] L. Bellaiche, A. Garcia, and D. Vanderbilt, Finite-temperature properties of Pb(Zr₁₋ₓTiₓ)O₃ alloys from first principles, Phys. Rev. Lett. 52, 5427 (2000).
[35] B. Noheda et al., A monoclinic ferroelectric phase in the Pb(Zr₁₋ₓTiₓ)O₃ solid solution, Appl. Phys. Lett. 74, 2059-2061 (1999).
[36] I. Grinberg, V. R. Cooper, and A. M. Rappe, Relationship between local structure and phase transitions of disordered solid solution, Nature 419, 909-911 (2002).
([37] P. G. de Gennes and J. Prost, The Physics of Liquid Crystals (Clarendon Press, Oxford, 1993).
[38] S. F. Edwards and P. W. Anderson, Theory of spin glasses, J. Phys. F: Metal Phys. 5, 965-974 (1975).
[39] V. Dubovik et al., Theory of the Curie-Weiss behavior of an aggregated magnetic suspension, J. Magn. Magn. Mater. 150, 105-118 (1995).
[40] N. Sicron et al., Nature of the ferroelectric phase transition in PbTiO₃, Phys. Rev. B 50, 13168-13180 (1994).
[41] J. Cardy & J. L. Jacobsen, Critical behavior of random-bond Potts models, Phys. Rev. Lett. 79, 4063-4066 (1997).
[42] I. P. Batra, P. Wurfel & B. D. Silverman, New type of first-order phase transition in ferroelectric thin films. Phys. Rev. Lett. 30, 384-387 (1973).
[43] M. Dawber, P. Chandra, P. B. Littlewood. & J. F. Scott, Depolarization corrections to the coercive field in thin-film ferroelectrics. J. Phys. C 15, L393-L398 (2003).
[44] A. A. Gorbatsevich & Yu. V. Kopaev, Toroidal order in crystals, Ferroelectrics 161, 321-334 (1994).
[45] I. Kornev, I., H. Fu. & L. Bellaiche, Ultrathin films of ferroelectric solid solutions under residual depolarizing field, preprint at (http://arxiv.org/cond-mat/0403484) (2004).
[46] D. D. Fong et al., Ferroelectricity in ultrathin perovskite films, Science 304, 1650-1653 (2004).
[47] B. G. Dernczyk, R. S. Rai & G. Thomas, Ferroelectric domain structure of lanthanum-modified lead titanate ceramics, J. Am. Ceram. Soc. 73, 615 (1999).
[48] B. Meyer & D. Vanderbilt, Ab-initio study of ferroelectric domain walls in PbTiO₃, Phys. Rev. B 65,104111(2002).
[49] I. I. Ivanchik, New type of first-order phase transition in ferroelectric thin films, Sov.Phys. Solid State 3,2705 (1962).

What is claimed is:

1. A method for storing data information, comprising the steps of:
providing a low dimensional nano-scale ferroelectric material having at least one vortex ring of polarization generating an ordered toroid moment switchable between at least two stable states; and
encoding said data information by switching said states.
